(19) United States
(12) Patent Application Publication
(10) Pub. No.: US 2025/0056849 A1
(43) Pub. Date: Feb. 13, 2025

(54) WORK FUNCTION METAL PATTERNING AND GATE CUT FOR NANOSHEET DEVICE

(71) Applicant: International Business Machines Corporation, Armonk, NY (US)

(72) Inventors: Juntao Li, Cohoes, NY (US); Ruilong Xie, Niskayuna, NY (US); Julien Frougier, Frougier, NY (US); Chanro Park, Clifton Park, NY (US); Min Gyu Sung, Latham, NY (US)

(21) Appl. No.: 18/448,386

(22) Filed: Aug. 11, 2023

(51) Int. Cl. H01L 29/06; H01L 21/8238; H01L 27/092; H01L 29/423; H01L 29/66; H01L 29/775; H01L 29/786

(52) U.S. Cl. CPC H01L 29/0673; H01L 21/823807; H01L 27/092; H01L 29/42392; H01L 29/66439; H01L 29/66545; H01L 29/775; H01L 29/78696

(57) ABSTRACT

A semiconductor device fabrication method is provided and includes building first and second nanosheet devices, locating a dielectric bar between the first and second nanosheet devices, forming, in the first nanosheet device, a first work function metal (WFM) and forming in the second nanosheet device, a second WFM that extends across the dielectric bar and the first WFM.

### BACKGROUND

The present invention generally relates to fabrication methods and resulting structures for semiconductor devices. More specifically, the present invention relates to a method and structure to improve work function metal (WFM) patterning and gate cut for a nanosheet device.

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

Embodiments of the invention are directed to a semiconductor device fabrication method. A non-limiting example of the semiconductor device fabrication method includes building first and second nanosheet devices, locating a dielectric bar between the first and second nanosheet devices, forming, in the first nanosheet device, a first work function metal (WFM) and forming, in the second nanosheet device, a second WFM that extends across the dielectric bar and the first WFM.

Embodiments of the present invention are directed to a semiconductor device. A non-limiting example of the semiconductor device includes a first nanosheet device including a first work function metal (WFM), a second nanosheet device and a dielectric bar located between the first and second nanosheet devices. The second nanosheet device includes a second WFM that extends across the dielectric bar and the first WFM.

Embodiments of the present invention are directed to semiconductor device. A non-limiting example of the semiconductor device includes a p-doped field effect transistor (PFET) device including a first work function metal (WFM), an n-doped field effect transistor (NFET) device and a dielectric bar located between the PFET and NFET devices. The NFET device includes a second WFM that extends across the dielectric bar and the first WFM.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a flow diagram illustrating a semiconductor device fabrication method in accordance with one or more embodiments of the present invention;

FIG. 2 is a top-down view of a semiconductor device assembly being fabricated in accordance with one or more embodiments of the present invention;

FIG. 3 is a side view of a semiconductor device assembly in an initial stage of being fabricated following initial nanosheet formation on a semiconductor substrate in accordance with one or more embodiments of the present invention;

FIG. 4 is a side view of a semiconductor device assembly in a second stage of being fabricated following hard mask deposition, nanosheet patterning, conformal dielectric liner deposition and second dielectric material filling and recessing executed with respect to the semiconductor device assembly of FIG. 3 in accordance with one or more embodiments of the present invention;

FIG. 5 is a side view of a semiconductor device assembly in a third stage of being fabricated following selective recessing of the conformal dielectric liner of FIG. 4, hard mask removal and dummy gate formation executed with respect to the semiconductor device assembly of FIG. 4 in accordance with one or more embodiments of the present invention;

FIG. 6 is a side view of a semiconductor device assembly in a fourth stage of being fabricated following dielectric layer removal by selective etch as well as top and bottom dielectric bar formation executed with respect to the semiconductor device assembly of FIG. 5 in accordance with one or more embodiments of the present invention;

FIG. 7 is a side view of a semiconductor device assembly in a fifth stage of being fabricated following nanosheet recessing, inner spacer formation, source/drain (S/D) epitaxy formation, interlayer dielectric (ILD) deposition, chemical mechanical polishing (CMP) and dummy gate and dielectric layer removal executed with respect to the semiconductor device assembly of FIG. 6 in accordance with one or more embodiments of the present invention;

FIG. 8 is a side view of a semiconductor device assembly in a sixth stage of being fabricated following liner deposition and annealing executed with respect to the semiconductor device assembly of FIG. 7 in accordance with one or more embodiments of the present invention;

FIG. 9 is a side view of a semiconductor device assembly in a seventh stage of being fabricated following first work function metal (WFM) deposition, WFM reactive ion etching and WFM patterning lithography executed with respect to the semiconductor device assembly of FIG. 8 in accordance with one or more embodiments of the present invention;

FIG. 10 is a side view of a semiconductor device assembly in an eighth stage of being fabricated following partial WFM removal executed with respect to the semiconductor device assembly of FIG. 9 in accordance with one or more embodiments of the present invention; and

FIG. 11 is a side view of a semiconductor device having been fabricated following organic planarization layer (OPL) stripping, second WFM deposition, metal gate material deposition, CMP and gate cut formation executed with respect to the semiconductor device assembly of FIG. 10 in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, field effect transistors (FETs) include doped source/drain regions that are formed in a semiconductor and separated by a channel region. A gate insulation layer is positioned about the channel region and a conductive gate electrode is positioned over or about the gate insulation layer. The gate insulation layer and the gate electrode together may be referred to as the gate stack for the device. By applying an appropriate voltage to the gate electrode, the channel region becomes conductive and current is allowed to flow from the source region to the drain region.

To improve the operating speed of the FETs, and to increase the density of FETs on an integrated circuit (IC), designs have gradually become smaller in size. Reductions to the size and the channel length in FETs can improve the switching speed of the FETs.

A number of challenges arise as feature sizes of FETs and ICs get smaller. For example, significant downsizing of traditional FETs may produce electrostatic issues and mobility degradation. Scaled-down FETs may have shorter gate lengths that make it more difficult to control the channel. Device architectures such as “gate-all-around” active nanostructures allow further scaling of ICs, in part, because the gate is structured to wrap around the channel, creating more surface area and better control. This structure can provide better control with lower leakage current, faster operations, and lower output resistance. Active nanostructures used to form the channel can include a semiconductor nanowire, i.e., a vertically or horizontally oriented thin wire, or a plurality of stacked nanosheets, i.e., a plurality of vertically spaced semiconductor sheets.

In very small transistors such as nanostructure FETs, metal gates are used to provide high performance. The threshold voltage of a FET is the minimum voltage required to create the conducting path between the source and drain. Metal gates include a gate metal with a work function metal (WFM) and a layer having a high dielectric constant (high-k) in a combination known as high-k metal gate (HKMG). The WFM is typically located between the high-k layer and the metal gate, and is used to tune the threshold voltage of the transistor. The work function is the minimum energy (usually measured in electron volts) needed to remove an electron from a solid to a point immediately outside the solid surface (or energy needed to move an electron from the Fermi energy level into vacuum), i.e., the final electron position is far from the surface on the atomic scale but still close to the solid on the macroscopic scale. Different transistors may require different threshold voltages, and therefore different WFMs. For example, a PFET (a FET with a channel that contains holes) may require a different WFM than an NFET (a FET with a channel that contains electrons).

It has been found that, in some nanostructure FETs, it can be difficult to pattern the WFM and to provide for a gate cut for a nanosheet device. For example, spacing between adjacent nanostructure FETs can be sufficient to prevent overetching from reaching the masked, first active nanostructure FET. However, as the distance between adjacent nanostructure FETs decreases (e.g., to less than 45 nanometers (nm) not including work function metal layer thickness), it has been discovered that the overetching may extend far enough to expose the first WFM of the masked, first active nanostructure FET. In some cases, the overetching can remove or damage the first WFM about the masked, first active nanostructure FET (removing it from at least a side portion of the channel material, including nanowire, fin or nanosheets thereof, and/or even from between nanowire or nanosheets, where provided). In any event, the overetching may impact the final device performance.

Turning now to an overview of the aspects of the invention, one or more embodiments of the invention address the above-described shortcomings of the prior art by providing a semiconductor device fabrication method and structure to improve work function metal (WFM) patterning and gate cut for a nanosheet device.

The above-described aspects of the invention address the shortcomings of the prior art by providing for a semiconductor device fabrication method is provided and includes building first and second nanosheet devices, locating a dielectric bar between the first and second nanosheet devices, forming, in the first nanosheet device, a first work function metal (WFM) and forming, in the second nanosheet device, a second WFM that extends across the dielectric bar and the first WFM.

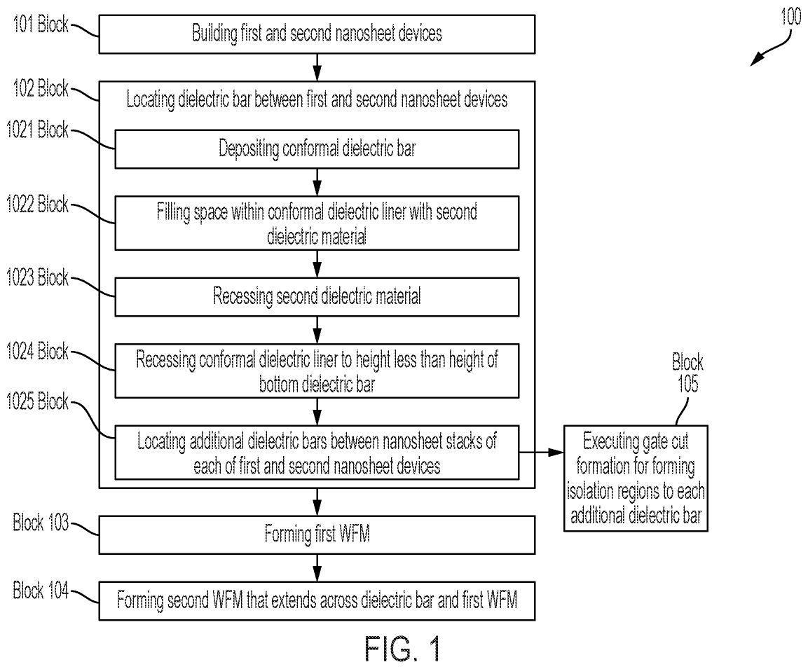

Turning now to a more detailed description of aspects of the present invention, FIG. 1 depicts a semiconductor device fabrication method 100. As shown in FIG. 1, the semiconductor device fabrication method 100 includes building first and second nanosheet devices (block 101), where one of the first and second devices is an NFET device and the other of the first and second devices is a PFET device. The semiconductor device fabrication method 100 further includes locating a dielectric bar between the first and second nanosheet devices (block 102) by, e.g., depositing a conformal dielectric liner (block 1021), filling space within the conformal dielectric liner with a second dielectric material (block 1022), which is different from the conformal dielectric liner, and recessing the second dielectric material (block 1023). In accordance with one or more embodiments of the present invention, each of the first and second nanosheet devices can include nanosheet stacks with a top dielectric bar and a bottom dielectric bar. In these or other cases, the semiconductor device fabrication method 100 further includes recessing the conformal dielectric liner to a height that is less than a height of the bottom dielectric bar (block 1024). In addition, the semiconductor device fabrication method 100 includes forming, in the first nanosheet device, a first WFM (block 103) and forming, in the second nanosheet device, a second WFM that extends across the dielectric bar and the first WFM (block 104).

In those cases in which each of the first nanosheet device and the second nanosheet device includes nanosheet stacks with a top dielectric bar and a bottom dielectric bar, the locating of the dielectric bar of block 102 can be executed such that a height of the dielectric bar exceeds a height of the bottom dielectric bar and is less than a height of the top dielectric bar. Also, in these or other cases, the locating of the dielectric bar of operation 102 can include locating additional dielectric bars between the nanosheet stacks of each of the first and second nanosheet devices (block 1025) and executing gate cut formation for forming gate contacts to each of the additional dielectric bars (block 105). In accordance with one or more embodiments of the present invention, in those cases in which the locating of the dielectric bar of operation 102 includes the locating of the additional dielectric bars between the nanosheet stacks of each of the first and second nanosheet devices of block 1025, there is an absence of the first WFM over the additional dielectric bar of the first nanosheet device and the second WFM includes a horizontal portion over the additional dielectric bar of the second nanosheet device.

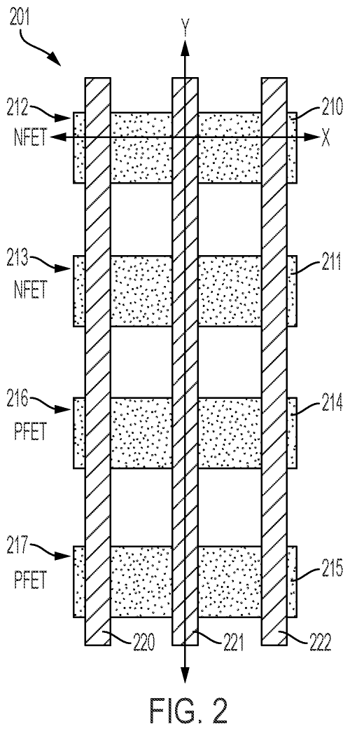

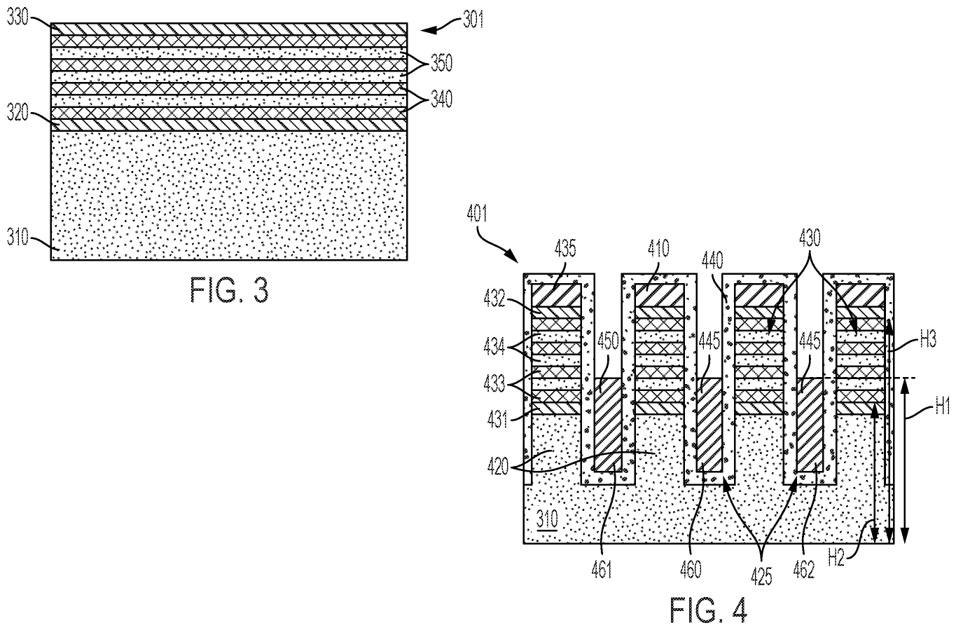

With continued reference to FIG. 1 and with additional reference to FIG. 2 and to FIGS. 3-11, the semiconductor device fabrication method 100 will now be described in greater detail.

FIG. 2 depicts a top-down view of a semiconductor device assembly 201 that is being fabricated. The semiconductor device assembly 201 includes nanosheet channel regions 210 and 211, which are each to be formed as NFET devices 212 and 213, respectively, nanosheet channel regions 214 and 215, which are each to be formed as FET devices 216 and 217, respectively, and gate regions 220, 221 and 222 extending across the nanosheet channel regions 210, 211, 214 and 215. For reference, the “Y” cross-sectional cut line of FIG. 2 corresponds to the perspective of the images in FIGS. 3-11.

With reference to FIG. 3, a semiconductor device assembly 301 is provided in an initial stage of being fabricated following initial nanosheet formation on a semiconductor substrate 310. The semiconductor device assembly 301 includes the semiconductor substrate 310, a first layer 320 of a first semiconductor material disposed on an uppermost surface of the semiconductor substrate 310, a second layer 330 of the first semiconductor material and interleaved layers 340 and 350 of second and third semiconductor materials that are interleaved with one another and interposed between the first layer 320 and the second layer 330. In accordance with one or more embodiments of the present invention, the semiconductor substrate 310 can include silicon, the first semiconductor material of the first and second layers 320 and 330 can include silicon-germanium55 (silicon-germanium having a relatively higher percentage of Ge (e.g., 55% Ge)), the second semiconductor material of the layers 340 can include silicon-germanium 30 (silicon-germanium having a relatively lower percentage of Ge (e.g., 30% Ge)), and the third semiconductor material of the layers 350 can include silicon. While it is to be understood that the materials referred to herein are examples and could be replaced by other materials, the following description will relate to the case of the materials referred to herein. This is being done for clarity and brevity and should not be interpreted as limiting the overall scope of the description or claims in any way.

With reference to FIG. 4, a semiconductor device assembly 401 is provided in a second stage of being fabricated following hard mask deposition, nanosheet patterning, conformal dielectric liner deposition and second dielectric material filling and recessing executed with respect to the semiconductor device assembly 301 of FIG. 3. The hard mask deposition forms a hard mask 410 on an uppermost surface of the second layer 330 of FIG. 3. The nanosheet patterning forms pillars 420 of the semiconductor substrate 310, trenches 425 between the pillars 420 and a nanosheet stack 430 on each of the pillars 420. Each nanosheet stack 430 includes a bottom bar 431, a top bar 432, interleaved bars 433 and 434 that are interleaved with one another and interposed between the bottom bar 431 and the top bar 432 and a hard mask remnant bar 435. The bottom bar 431 is formed as a remainder of the first layer 320 of FIG. 3 and includes the first semiconductor material. The top bar 432 is formed as a remainder of the second layer 330 of FIG. 3 and includes the first semiconductor material. The interleaved bars 433 and 434 are respectively formed as remainders of the interleaved layers 340 and 350 of FIG. 3 and respectively include the second and third semiconductor materials. The conformal dielectric liner deposition results in the formation of a conformal dielectric liner 440 along upper surfaces and sidewalls of the nanosheet stacks 430, along sidewalls of the pillars 420 and along bottom surfaces of the trenches 425. The conformal semiconductor liner 440 is thus formed to define interior spaces 445 corresponding to the trenches 425. Second dielectric material 450, which is different from the dielectric material of the conformal dielectric liner 440, is filled into the interior spaces 445 and recessed to a height H1 that exceeds a height H2 of the bottom bar 431 and that is less than a height H3 of the top bar 432 to form a dielectric bar 460 and additional dielectric bars 461 and 462 all with the height H1.

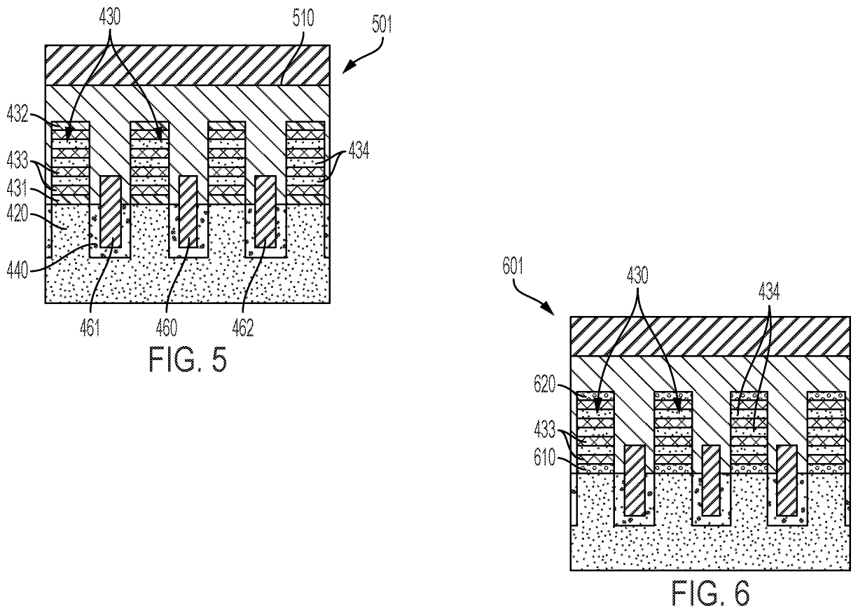

With reference to FIG. 5, a semiconductor device assembly 501 is provided in a third stage of being fabricated following selective recessing of the conformal dielectric liner 440 of FIG. 4, hard mask removal and dummy gate formation executed with respect to the semiconductor device assembly 401 of FIG. 4. The selective recessing of the conformal dielectric liner 440 results in the removal of the portions of the conformal dielectric liner 440 formed along the upper surfaces and the sidewalls of the nanosheet stacks 430 such that upper edges of the remainders of the conformal dielectric liner 440 terminate at a height of the uppermost surfaces of the pillars 420 and below the bottom bar 431. The remainders of the conformal dielectric liners 440 can thus be regarded as shallow trench isolation (STI) between neighboring nanosheet stacks 430. The hard mask removal results in the removal of the hard mask remnant bar 435 of FIG. 4 from the nanosheet stacks 430 and the dummy gate formation results in the formation of a dummy gate 510 around the nanosheet stacks 430 and around respective portions of the dielectric bar 460 and the additional dielectric bars 461 and 462 that protrude upwardly from the remainders of the conformal dielectric liners 440.

With reference to FIG. 6, a semiconductor device assembly 601 is provided in a fourth stage of being fabricated following dielectric layer removal by selective etch, spacer formation and etch back processing in gate regions (i.e., gate regions 220, 221 and 222 of FIG. 2) and top and bottom dielectric bar formation executed with respect to the semiconductor device 501 assembly of FIG. 5. The dielectric layer removal by selective etch results in removal of the bottom bars 431 and the top bars 432 of FIG. 5. The top and bottom dielectric bar formation results in the formation of bottom dielectric bars 610 in the spaces opened by the removal of the bottom bars 431 and in the formation of top dielectric bars 620 in the spaces opened by the removal of the top bars 432 in the nanosheet stacks 430.

With reference to FIG. 7, a semiconductor device assembly 701 is provided in a fifth stage of being fabricated following nanosheet recessing, inner spacer formation, source/drain (S/D) epitaxy formation, interlayer dielectric (ILD) deposition, chemical mechanical polishing (CMP) in the gate regions (i.e., gate regions 220, 221 and 222 of FIG. 2) and following dummy gate and dielectric layer removal executed with respect to the semiconductor device assembly 601 of FIG. 6. The dummy gate removal removes the dummy gate 510 of FIG. 5. The bars 433 between the nanosheet stacks 430 are also selectively removed. Each of the remaining nanosheet stacks 430 includes the bottom dielectric bar 610, the top dielectric bar 620 and the bars 434 interposed between the bottom dielectric bar 610 and the top dielectric bar 620.

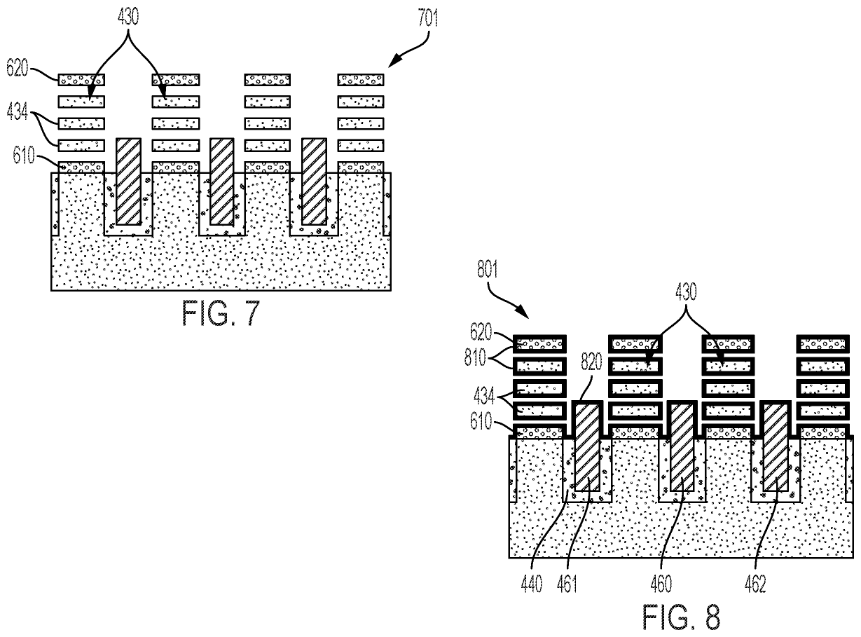

With reference to FIG. 8, a semiconductor device assembly 801 is provided in a sixth stage of being fabricated following a high-K gate dielectric layer deposition and annealing executed with respect to the semiconductor device assembly 701 of FIG. 7. An anneal process can be performed to improve the reliability of the high-K gate dielectric layer. For example, a conformal sacrificial titanium nitride layer (not shown) can be deposited on the high-K gate dielectric layer and a sacrificial amorphous silicon layer (not shown) can be deposited onto the sacrificial titanium nitride layer. A reliability anneal can then be performed in order to modify the molecular structure of the high-K gate dielectric layer so as to improve its reliability (e.g., to minimize gate leakage, negative bias temperature instability, etc.). Following the reliability anneal, cleaning processes can be performed to completely remove the sacrificial amorphous silicon and titanium nitride layers. The semiconductor device assembly 801 thus includes high-K gate dielectric layers 810 surrounding each of the top dielectric bars 620, each of the bars 434 and a high-K gate dielectric layer 820 disposed on exposed surfaces of the bottom dielectric bars 610, the upper edges of the remainders of the conformal dielectric liners 440 and the respective portions of the dielectric bar 460 and the additional dielectric bars 461 and 462 that protrude upwardly from the remainders of the conformal dielectric liners 440. The high-K gate dielectric layers 810 and the high-K gate dielectric layer 820 can include, but are not limited to, metal oxides such as hafnium oxide (HfO₂), hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg).

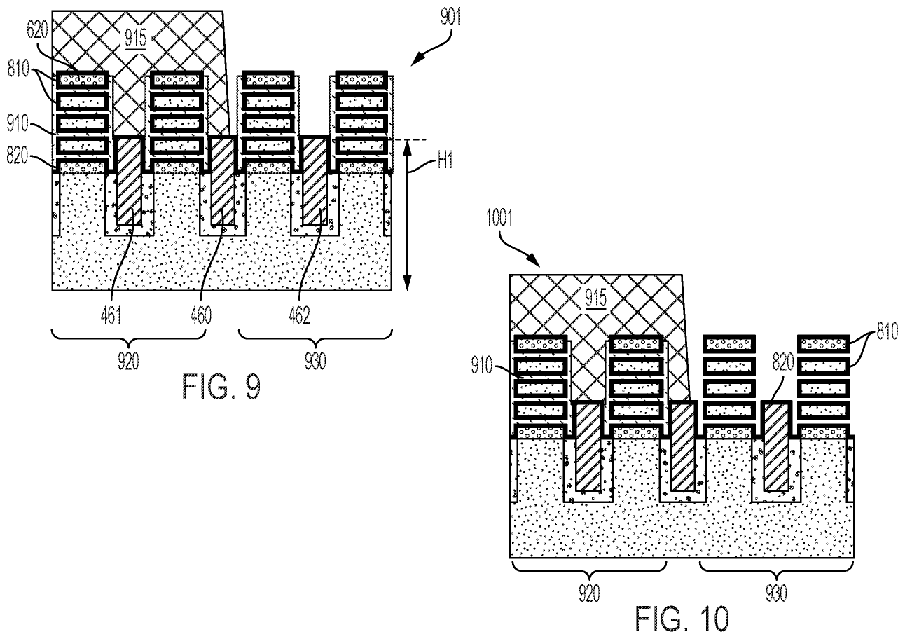

With reference to FIG. 9, a semiconductor device assembly 901 is provided in a seventh stage of being fabricated following first WFM deposition, WFM reactive ion etching (RIE) and WFM patterning lithography executed with respect to the semiconductor device assembly 801 of FIG. 8. The first WFM deposition results in the first WFM 910 being formed around and on each of the high-K gate dielectric layers 810 and the high-K gate dielectric layer 820 of FIG. 8. The WFM reactive ion etching can be executed as an anisotropic RIE and results in horizontal portions of the first WFM 910 being removed to expose uppermost portions of the high-K gate dielectric layers 810 surrounding the top dielectric bars 620 and to expose the portions of the high-K gate dielectric layer 820 disposed on the dielectric bar 460 and the additional dielectric bars 461 and 462. The presence of the uppermost portions of the high-K gate dielectric layers 810 surrounding the top dielectric bars 620 serves to protect the high-k metal gate over the top dielectric bars 620. The WFM patterning lithography results in a formation of an organic planarization layer (OPL) 915 being formed in what will be the PFET region 920 (the other region will be the NFET region 930).

With the dielectric bar 460 having the height H1 (see FIG. 4), the dielectric bar 460 is effectively raised to provide a relatively large process window in WFM patterning misalignment given that the OPL 915 RIE profile is tapered as shown in FIG. 9. Also, with the horizontal portion of the first WFM 910 being removed to expose the portion of the high-K gate dielectric layer 820 disposed on the dielectric bar 460, there is no undercut present at the portion of the high-K gate dielectric layer 820 disposed on the dielectric bar 460.

With reference to FIG. 10, a semiconductor device assembly 1001 is provided in an eighth stage of being fabricated following partial WFM removal executed with respect to the semiconductor device assembly 901 of FIG. 9. The partial WFM removal uses the masking provided by the OPL 915 of FIG. 9 to remove the portion of the first WFM 910 in the NFET region 930 and to expose the high-K gate dielectric layers 810 and the portion of the high-K gate dielectric layer 820 in the NFET region 930.

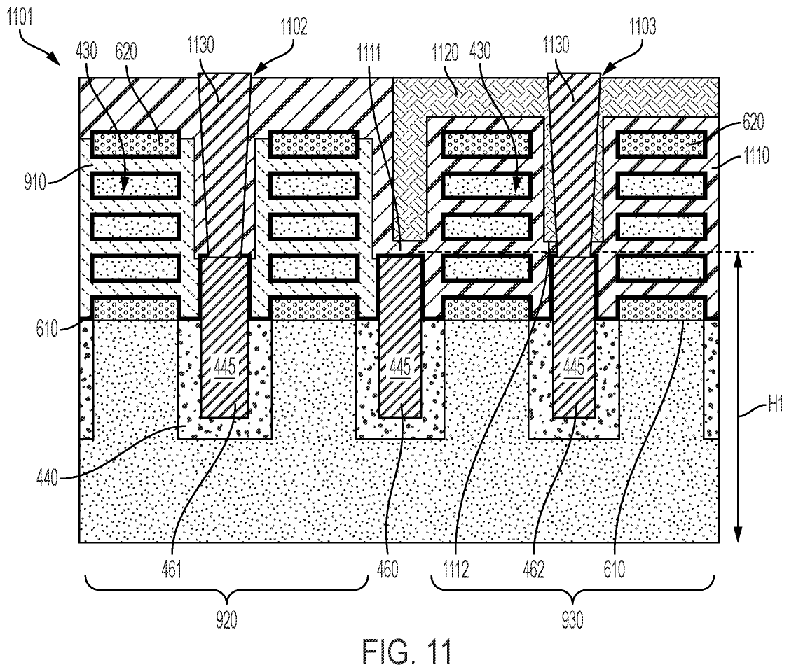

With reference to FIG. 11, a semiconductor device 1101 having been fabricated is provided following a stripping of the OPL 915 of FIG. 9, second WFM deposition to form a second WFM 1110 in the NFET region 930 and in the PFET region 920, metal gate material deposition to form a metal gate 1120 in the NFET region 930, CMP and gate cut formation executed with respect to the semiconductor device assembly 1001 of FIG. 10. The gate cut formation allows for the formation of an isolation region 1130 that extend to the additional dielectric bars 461 and 462 in the PFET region 920 and the NFET region 930.

With the additional dielectric bars 461 and 462 having the height H1 (see FIG. 4), the additional dielectric bars 461 and 462 are effectively raised to provide a relatively large process window for gate cut patterning given that the isolation regions 1130 are tapered as well as isolation regions 1130 having relatively reduced aspect ratios. In addition, with the additional dielectric bars 461 and 462 being effectively raised, the gate cut formation is executed to a relatively lesser depth and thus provides for improved gate cut formation control.

As shown in FIG. 11, the semiconductor device 1101 therefore includes a PFET device 1102 that includes the first WFM 910 of FIG. 9, an NFET device 1103 and a dielectric bar 460 located between the PFET device 1102 and the NFET device 1103. The NFET device 1103 includes the second WFM 1110 that extends across the dielectric bar 460 and the first WFM 910. The semiconductor device 1101 further includes the conformal dielectric liners 440 defining the interior spaces 445 in which the dielectric bar 460 and the additional dielectric bars 461 and 462 are disposed. Each of the NFET and PFET devices 1102 and 1103 includes nanosheet stacks 430 with a top dielectric bar 620 and a bottom dielectric bar 610, each of the conformal dielectric liners 440 has upper edges that terminate at a height below the bottom dielectric bar 610 and each of the dielectric bar 460 and the additional dielectric bars 461 and 462 has the height H1 that exceeds a height of the bottom dielectric bar 610 and is less than a height of the top dielectric bar 620. As shown in FIG. 11, there is an absence of the first WFM 910 over the additional dielectric bar 461 of the PFET device 1102 and the second WFM 1110 includes horizontal portions 1111 and 1112 over the dielectric bar 460 and over the additional dielectric bar 462 of the NFET device 1103, respectively.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device fabrication method, comprising:
building first and second nanosheet devices;
locating a dielectric bar between the first and second nanosheet devices;
forming, in the first nanosheet device, a first work function metal (WFM); and
forming, in the second nanosheet device, a second WFM that extends across the dielectric bar and the first WFM.

2. The semiconductor device fabrication method according to claim 1, wherein:
one of the first and second nanosheet devices comprises an n-doped field effect transistor (NFET) device, and
the other of the first and second nanosheet devices comprises a p-doped field effect transistor (PFET) device.

3. The semiconductor device fabrication method according to claim 1, wherein the locating of the dielectric bar comprises:
depositing a conformal dielectric liner;
filling space within the conformal dielectric liner with a second dielectric material different from the conformal dielectric liner; and
recessing the second dielectric material.

4. The semiconductor device fabrication method according to claim 3, wherein:
each of the first and second nanosheet devices comprises nanosheet stacks with a top dielectric bar and a bottom dielectric bar, and
the semiconductor device fabrication method further comprises recessing the conformal dielectric liner to a height that is less than a height of the bottom dielectric bar.

5. The semiconductor device fabrication method according to claim 1, wherein:
each of the first and second nanosheet devices comprises nanosheet stacks with a top dielectric bar and a bottom dielectric bar, and
the locating of the dielectric bar is executed such that a height of the dielectric bar exceeds a height of the bottom dielectric bar and is less than a height of the top dielectric bar.

6. The semiconductor device fabrication method according to claim 1, wherein:
each of the first and second nanosheet devices comprises nanosheet stacks,
the locating of the dielectric bar comprises locating additional dielectric bars between the nanosheet stacks of each of the first and second nanosheet devices, and
the semiconductor device fabrication method further comprises executing gate cut formation for forming gate contacts to each of the additional dielectric bars.

7. The semiconductor device fabrication method according to claim 6, wherein:
there is an absence of the first WFM over the additional dielectric bar of the first nanosheet device, and
the second WFM comprises a horizontal portion over the additional dielectric bar of the second nanosheet device.

8. A semiconductor device, comprising:
a first nanosheet device comprising a first work function metal (WFM);
a second nanosheet device; and
a dielectric bar located between the first and second nanosheet devices,
the second nanosheet device comprising a second WFM that extends across the dielectric bar and the first WFM.

9. The semiconductor device according to claim 8, wherein:
one of the first and second nanosheet devices comprises an n-doped field effect transistor (NFET) device, and
the other of the first and second nanosheet devices comprises a p-doped field effect transistor (PFET) device.

10. The semiconductor device according to claim 8, further comprising a conformal dielectric liner defining an interior space in which the dielectric bar is disposed.

11. The semiconductor device according to claim 10, wherein the dielectric bar comprises a second dielectric material different from the conformal dielectric liner.

12. The semiconductor device according to claim 10, wherein:
each of the first and second nanosheet devices comprises nanosheet stacks with a top dielectric bar and a bottom dielectric bar, and
the conformal dielectric liner has a height that is less than a height of the bottom dielectric bar.

13. The semiconductor device according to claim 8, wherein:
each of the first and second nanosheet devices comprises nanosheet stacks with a top dielectric bar and a bottom dielectric bar, and
a height of the dielectric bar exceeds a height of the bottom dielectric bar and is less than a height of the top dielectric bar.

14. The semiconductor device according to claim 8, wherein:
each of the first and second nanosheet devices comprises nanosheet stacks, and
the semiconductor device further comprises additional dielectric bars between the nanosheet stacks of each of the first and second nanosheet devices and gate contacts to each of the additional dielectric bars.

15. The semiconductor device according to claim 14, wherein:
there is an absence of the first WFM over the additional dielectric bar of the first nanosheet device, and
the second WFM comprises a horizontal portion over the additional dielectric bar of the second nanosheet device.

16. A semiconductor device, comprising:
a p-doped field effect transistor (PFET) device comprising a first work function metal (WFM);
an n-doped field effect transistor (NFET) device; and
a dielectric bar located between the PFET and NFET devices,
the NFET device comprising a second WFM that extends across the dielectric bar and the first WFM.

17. The semiconductor device according to claim 16, wherein:
the semiconductor device further comprises a conformal dielectric liner defining an interior space in which the dielectric bar is disposed,
the dielectric bar comprises a second dielectric material different from the conformal dielectric liner,
each of the NFET and PFET devices comprises nanosheet stacks with a top dielectric bar and a bottom dielectric bar, and
the conformal dielectric liner has a height that is less than a height of the bottom dielectric bar.

18. The semiconductor device according to claim 16, wherein:
each of the NFET and PFET devices comprises nanosheet stacks with a top dielectric bar and a bottom dielectric bar, and
a height of the dielectric bar exceeds a height of the bottom dielectric bar and is less than a height of the top dielectric bar.

19. The semiconductor device according to claim 16, wherein:
each of the NFET and PFET devices comprises nanosheet stacks, and
the semiconductor device further comprises additional dielectric bars between the nanosheet stacks of each of the NFET and PFET devices and gate contacts to each of the additional dielectric bars.

20. The semiconductor device according to claim 19, wherein:
there is an absence of the first WFM over the additional dielectric bar of the PFET device, and
the second WFM comprises a horizontal portion over the additional dielectric bar of the NFET device.
